(19) United States
(12) Patent Application Publication
(10) Pub. No.: US 2008/0130815 A1
(43) Pub. Date: Jun. 5, 2008

(54) Selective tracking of serial communication link data

(76) Inventors: S. Reji Kumar, University Place, WA (US); Arnaud Forestier, Irvine, CA (US); Adarsh Panikkar, Tacoma, WA (US); Kersi H. Vakil, Olympia, WA (US)

Correspondence Address: LEE & HAYES, PLLC, P.O. BOX 52050, MINNEAPOLIS, MN, 55402, US

(21) Appl. No.: 11/633,917

(22) Filed: Dec. 5, 2006

(51) Int. Cl. H03D 3/24

(52) U.S. Cl. 375/373

(57) ABSTRACT

Embodiments to selectively track serial communication link data are presented herein.

### BACKGROUND

Various serial communication links may process data with the help of numerous devices, such as computers or the like. These devices often include associated circuitry that allows the device to receive and process the data. This circuitry draws power from a power source and, in turn, creates heat that is to be dissipated throughout the device and into the device's environment. This heat, as well as the power consumed by the circuitry, may limit the functionality of the circuitry itself as well as other functionality in the device's environment.

### BRIEF DESCRIPTION OF THE DRAWINGS

FIG. 1 is a block diagram of a transmitter and a receiver in accordance with an embodiment.

FIG. 2 is a representation of incoming data and phase clocks in accordance with an embodiment.

FIG. 3 is a representation of a data lane comprising sync packets and possible states of a tracking signal in accordance with an embodiment.

FIG. 4 is a representation of multiple data lanes comprising sync packets and possible states of a tracking signal in accordance with an embodiment.

FIG. 5 is a flow diagram that illustrates acts in accordance with an embodiment.

FIG. 6 is a diagram that illustrates an exemplary system in which devices formed in accordance with the embodiments described herein can be used, in accordance with an embodiment.

### DETAILED DESCRIPTION

In the discussion that follows, specific implementation examples and methods are provided under the headings “Implementation Examples” and “Exemplary Methods”. It is to be appreciated and understood that such implementation examples and exemplary methods are not to be used to limit application of the claimed subject matter to only these examples. Rather, changes and modifications can be made without departing from the spirit and scope of the claimed subject matter.

Implementation Examples

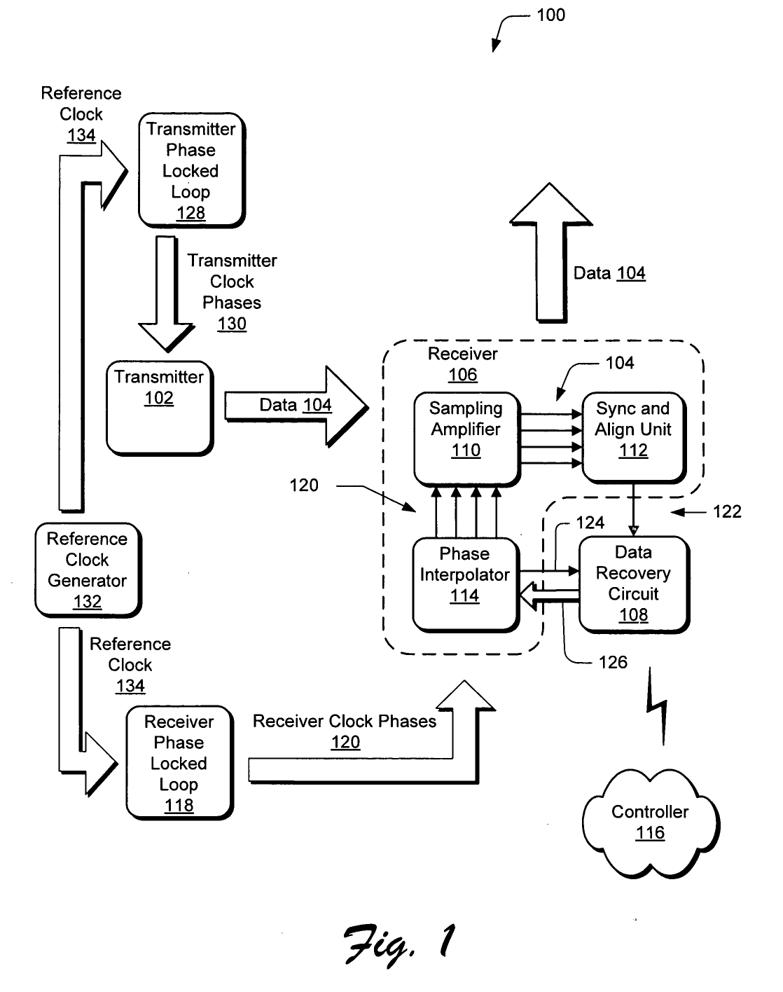

FIG. 1 depicts a serial communications system 100 comprising a transmitter 102 transmitting data 104 to a receiver 106. System 100 may comprise any serial communication system capable of transmitting data of any form from a transmitter to a receiver. Non-limiting but illustrative examples of such data transfers may include data sent over a serial input/output (I/O) interface, such as a fully-buffered dual in-line memory module (FB-DIMM), a single in-line memory module (SIMM), a universal serial bus (USB), a peripheral component interface (PCI), a PCI Express, a Common System Interface (CSI), a fiber channel, an Ethernet network, or various wireless signaling protocols. This data transfer may also merely comprise data transferred over memory integrated circuits, data transfer between processors, data transfer within processors, data transfer from an operator to the processor, or the like.

As depicted in FIG. 1, data 104 may travel from transmitter 102 to receiver 106 and out of receiver 106 to other portions of the system. In some implementations, data 104 may exit receiver 104 and travel to a data-processing portion of the system. Receiver 106, meanwhile, may sample or extract data 104 in some instances in order to obtain or read the information contained therein.

Data 104 may enter receiver 106 having a certain clock phase, which, in some implementations, may be equal or approximately equal to that of a clock of transmitter 102. System 100 may also include a data recovery circuit (i.e., clock and data recovery) 108 or the like. In some instances, data recovery circuit 108 may serve to recover the clock phase of data 104, which again may comprise a clock phase of transmitter 102. Recovering the clock phase of data 104 may allow for data recovery circuit 108 to ensure that receiver 106 is sampling or extracting from data 104 at a proper location, such as an approximate center of the data. Sampling at approximately the center of data 104 may allow for proper reading of the data, and may, in some instances, reduce a bit error rate of the read data. It is noted that receiver 106 or other circuitry may also serve to allow receiver 106 to sample at a proper location of data 104. Generally, data recovery circuit 108 and/or receiver 106 “locks onto” the appropriate portion of data 104 when it initially enters receiver 106, after which point this circuitry may track any low frequency drift or jitter that could alter the phase of incoming data 104.

With knowledge of whether or not incoming data 104 is being sampled at a proper location (e.g. at the center of the data), data recovery circuit 108 and/or associated circuitry of receiver 106 may continue to track the transmitted clock phase and adjust the sampling position of the receiver. In some instances, data recovery circuit 108 and/or associated circuitry of receiver 106 may strive to adjust the sampling position of receiver 106 to approximate an optimal sampling position in response to this tracking. As such, receiver 106 and/or data recovery circuit 108 may define a feedback loop that continuously monitors and adjusts a sampling position of the receiver on incoming data 104 to reduce the bit error rate of read data 104. As discussed below, however, this feedback loop—or portions of it—may be shutdown in some instances despite the continued influx of data 104 to receiver 106.

As further depicted by FIG. 1, receiver 106 may comprise one or more sampling amplifiers 110, one or more sync and align units 112, as well as one or more phase interpolators 114. In instances where portions of receiver 106 and/or data recovery circuit 108 are turned off for periods of time, mentioned briefly above, system 100 may also comprise a controller 116. As discussed in more detail below, controller 116 may serve to turn on and off some of these components.

Furthermore, system 100 may also include a receiver phased lock loop (PLL) 118. Receiver PLL 118 may introduce one or more receiver phase clocks 120 into receiver 106. More specifically, in some implementations receiver PLL 118 may provide receiver phase clocks 120 into phase interpolator 114. Also as shown in FIG. 1, sampling amplifier 110 may receive receiver phase clocks 120 from phase interpolator 114 as well as data 104 from transmitter 102. Sampling amplifier 110 may then output data 104. This data 104 may travel to other parts of the system, illustrated by upward arrow 104, as well as to sync and align unit 112. Data 104 may output sampling amplifier 110 in the form of data and/or edge samples, as discussed in detail below. Sync and align unit 112 may in turn consolidate some or all of these data and/or edge samples of data 104 into a single clock phase, possibly a clock phase of data recovery circuit 108. As shown in FIG. 1, phase interpolator 114 may input clock 124 to data recovery circuit 108. Finally, data recovery circuit 108 may increment or decrement the sampling position of receiver 106 by giving instructions to phase interpolator 114. Arrow 126 of FIG. 1 represents these instructions in some instances.

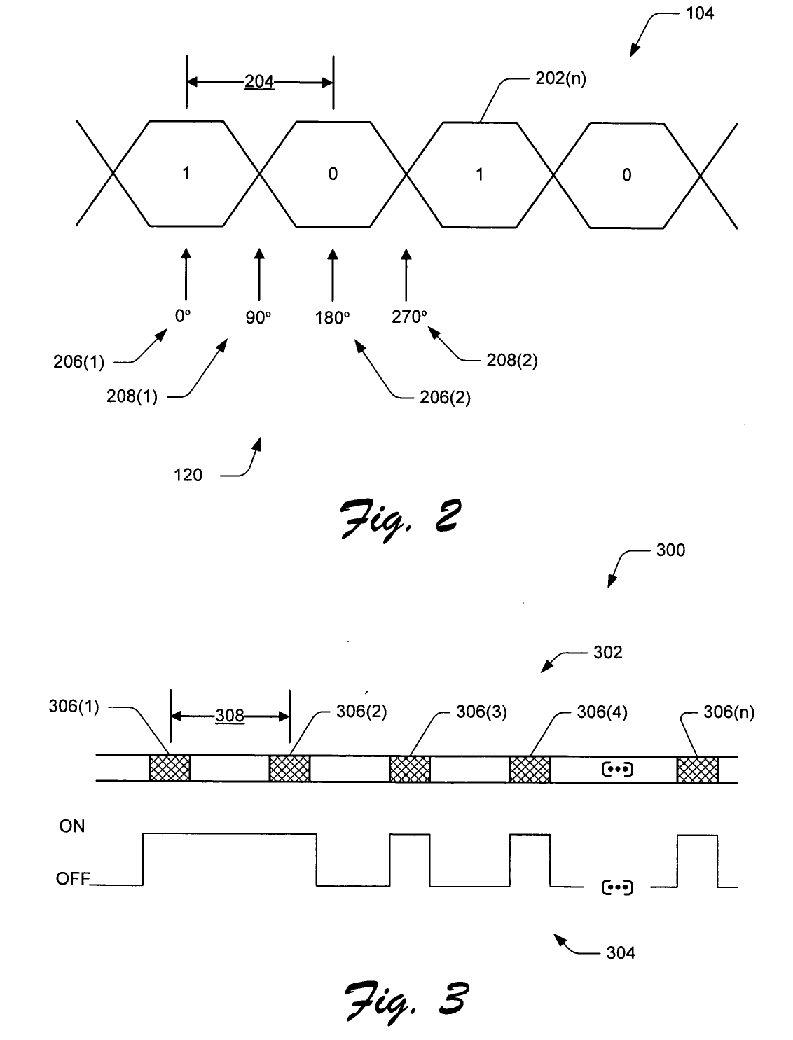

As illustrated, system 100 may also include a transmitter PLL 128, which may introduce one or more transmitter phase clocks 130. The number of transmitter phase clocks 130 may differ from the number of receiver phase clocks 120. In some instances, a greater number of receiver phase clocks (e.g., four) may exist than transmitter phase clocks (e.g., two). Furthermore, note that system 100 may further include a reference clock generator 132, which may provide a reference clock 134 into both transmitter PLL 128 and receiver PLL 118. Reference clock 134 may provide a reference signal to both of these components so as to set a bit error rate. Such a reference signal, which may be of a relatively lower frequency as compared to transmitter and receiver clocks, may function to approximately equalize the bit error rate of both transmitter 102 and receiver 106. Attention will return to the components of FIG. 1 after a more detailed discussion of the tracking of a phase of inputted data, as well as FIGS. 2-4.

Reference is now made to FIG. 2, which depicts an embodiment of data 104. Data 104 may comprise one or more symbols 202(n), such as bits, in some implementations. In some of these implementations, data 104 may comprise binary code. In the illustrated example, data 104 comprises bits, each of which are separated by a unit interval 204. Unit interval 204 is the amount of time it takes to send one symbol of data from transmitter 102 to receiver 106. Furthermore, each symbol or bit may comprise a center and an edge. Receiver 106 may strive to sample data 104 at or near this center so as to properly extract the information therein. It is also noted that a symbol followed by a differing symbol may comprise what is known as a “transition”. In FIG. 2, for instance, each time a logic “0” is followed by a logic “1”, or vice versa, a transition exists. Of course, while the unit interval 204 is shown as the length of time between two centers of a symbol, it is also equal to the length of time between two edges of a symbol.

FIG. 2 also depicts one or more receiver phase clocks 120 from FIG. 1. Although receiver phase clocks 120 are illustrated as four clocks, any number of phase clocks may be used. Here, receiver phase clocks 120 comprise two data clocks 206(1) and 206(2), as well as two edge clocks 208(1) and 208(2). Receiver 106 and/or data recovery circuit 108 may cause data clocks 206(1)-(2) to fall on or near an approximate center of a symbol or bit, while causing edge clocks to fall on or near an edge of a symbol or bit (and possibly the edge of a transition). As such, FIG. 2 illustrates data clocks 206(1)-(2) as falling near a center of a bit at 0° and 180°, respectively, while edge clocks 208(1)-(2) are illustrated as falling near an edge of a bit at 90° and 270°, respectively. Thus, FIG. 2 may illustrate an appropriate phase clock location to allow for proper sampling or extraction of information from data 104.

In some instances, an edge of a transition may be useful in determining a length of a unit interval, such as unit interval 204. By figuring out where transitions occur, the data's 104 clock phase (which may be equal to the transmitter clock phase) may be recovered in some instances. Furthermore, receiver 106 and/or data recovery circuit 108 may continue to sample the incoming data 104 to determine where an appropriate sampling point is located and to continue to make adjustments to that point. For instance, if data recovery circuit 108 determines that data clocks 206(1)-(2) do not fall on or near a center of a symbol (or that edge clocks 208(1)-(2) do not fall at edges of a symbol), it may instruct phase interpolator 114 to increment or decrement receiver phase clocks 120. That is, data recovery circuit 108 may direct phase interpolator 114 and/or receiver 106 to move the arrows shown in FIG. 2 to the right or left, respectively.

Unfortunately, while this phase tracking of a clock phase continues, a family of circuits within data recovery circuit 108 and/or receiver 106 may continue to run. Thus, these circuits may use power and, in some instances, create heat to be dissipated. Furthermore, a signal transition may not occur during each signal period. In some instances, for example, a relatively long amount of time may elapse during which data 104 has no or very few signal transitions (e.g., data 104 includes a string of logic zeroes). In these instances, the benefit in attempting to recover the phase of the transmitted clock and/or phase of the data 104 and adjusting the sampling position of receiver 106 may be minimal. Thus, in some instances this continuous monitoring may consume extra power and produce extra heat.

Thus, in some implementations, data recovery circuit 108 and/or portions of receiver 106 may be shut down for periods of time during which receiver 106 continues to receive incoming data 104. This may be aided, in some instances, by knowledge of the signaling protocol that is used. This is because a signaling protocol may guarantee a certain transition density. If FB-DIMM is used, for example, then a transition density of six transitions every 512 unit intervals may exist by definition. Furthermore, these six transitions may be specified by protocol to occur within close proximity to each other, such as back-to-back. In some instances, these transitions may be termed “sync packets” or “training packets”. In some implementations, the host of the platform may strive to ensure a correct timing and frequency of the sync packets. Therefore, with knowledge of the protocol, and hence with knowledge of when these sync packets will occur, the feedback loop discussed above may be able to selectively—rather than continuously—track the phase of the transmitted clock while still maintaining an equivalent bit error rate.

FIG. 3 depicts a representation 300 of incoming data lane 302 as well as a tracking enable state 304. Data lane 302 may comprise many of the same qualities discussed above in regards to data 104. For instance, data lane 302 may comprise symbols or bits in the manner shown in FIG. 2. Here, data lane 302 is shown to also include sync packets 306(1)-(n). Again, these sync packets may include a certain number of transitions within a certain time, as specified by protocol. Again, these properties may also differ according to protocol. Also as shown in FIG. 3, sync packets 306(1)-(n) may be separated by a time 308, which may generally be consistent. Again, this may be specified by protocol in some instances.

With knowledge of time 308, tracking of the phase of received data within a data lane 304 may occur during receipt of sync packets 206(1)-(n). Further, tracking of the phase of data within data lane 304 may be selectively turned off after the receiver has “locked onto” the data and may continue to remain off when sync packets are generally not scheduled to be received. In this manner, tracking may be enabled at a “beat rate”—that is at a rate equal to the time in between sync packets. It is also noted that tracking may be selectively turned off and on at any other schedule rate, or it could be done randomly. Furthermore, tracking may be enabled every whole number of a beat rate. For example, every other or every third sync packet could be tracked in an “extended power savings mode”. Because tracking may be intermittently enabled and disabled (i.e., turned on and off) in this manner, power may be saved and heat output may be reduced with relatively little or no perceptible impact on performance.

Returning to FIG. 3, however, tracking enable state 304 is shown to be “ON” during receipt of the first two packets. Therefore, data within data lane 302 may be generally continuously monitored during receipt of the first two sync packets 306(1)-(2). At this point, the circuitry may determine distance 308 and, hence, the beat rate. In other words, the system may set a beacon or a marker after seeing first sync packet 306(1) and may start a timer or counter at that moment. The system may then stop the timer or counter after second sync packet 306(2) arrives, thus defining the beat rate. This initial determination may be made by a core of the device (e.g., a host controller of the device) in some implementations.

After this determination, tracking enable state 304 may be cycled between the “ON” and “OFF” states. Furthermore, in some instances the transmitted clock phase may not drift (i.e., display “jitter”) from one sync packet to the next. Therefore, the receiver 106 and/or data recovery circuit 108 may make relatively minor adjustments to the sampling position of receiver 106, without increasing or drastically increasing the bit error rate of the read data. It is again noted, however, that tracking may be enabled at other rates (e.g., every third sync packet) or even randomly. This setting may be a manually-adjustable configuration in some implementations.

Furthermore, it is noted that the feedback loop of system 100, depicted in FIG. 1, may be utilized for multiple data lanes or for a single data lane. In some implementations, the feedback loop of system 100 may thus be replicated for another data lane. That is, if system 100 exists upon an integrated circuit or the like, the integrated circuit may comprise multiple receivers 106, data recovery circuits 108, and/or controllers 116. Receiver PLL 118 may generate clock phases as discussed above, and may deliver these clock phases commonly to each receiver 106. Each receiver 106, meanwhile, may have a phase interpolator 114 and a corresponding data recovery circuit 108. This circuitry may thus track a phase of the incoming data of a corresponding data lane and may adjust a sampling position of corresponding receiver 106. Although this may increase circuitry, it may also serve to increase power savings, as the tracking of each phase of data from each data lane may be tracked for minimal periods of time.

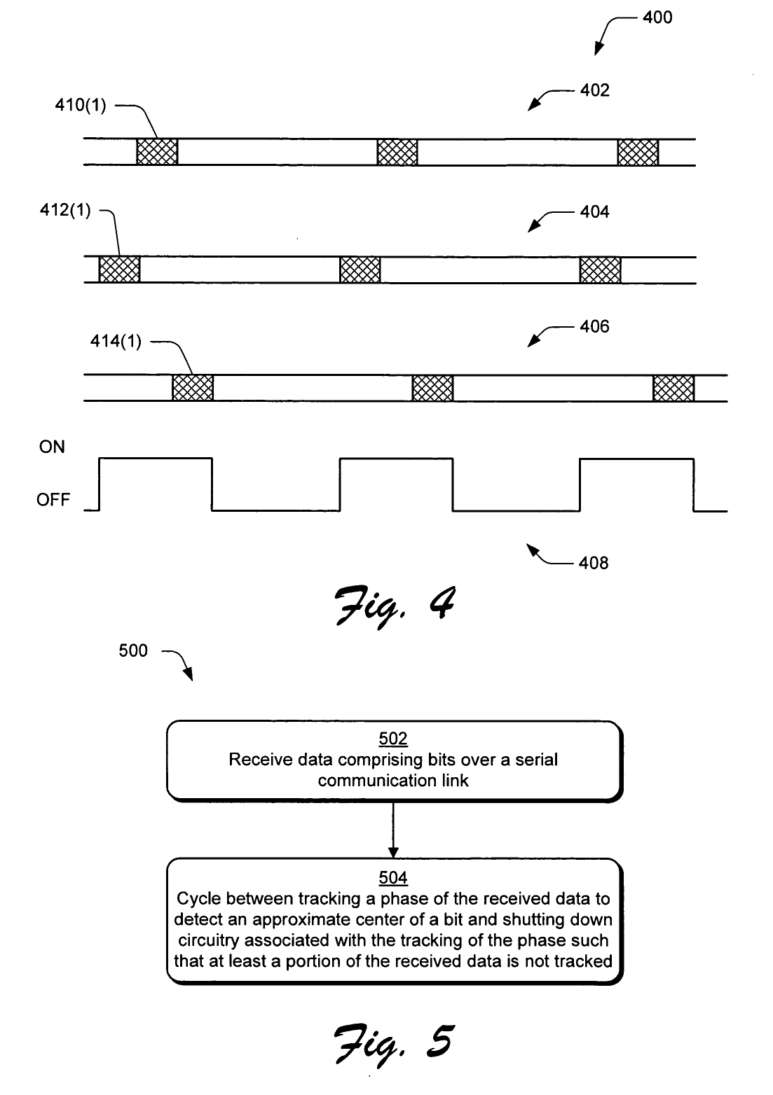

This is contrasted with implementations utilizing a single feedback loop and a common tracking enable signal for multiple data lanes, which may result in tracking states depicted in FIG. 4. FIG. 4 depicts a representation 400 of incoming data lanes 402, 404, and 406, as well as a tracking enable state 408. Data lanes 402, 404, and 406 may comprise many of the same qualities discussed above in regards to data 104. For instance, data lane 402, 404 and 406 may comprise symbols or bits in the manner shown in FIG. 2. Here, each data lane 402, 404, and 406 is shown to also include sync packets, such as sync packets 410(1), 412(1), and 414(1), respectively. Again, these sync packets may include a certain number of transitions within a certain time, as specified by protocol. Again, these properties may also differ according to protocol. Furthermore, sync packets of each data lane 402, 404, and 406 may again be separated by a certain time or distance, which may again define a beat rate. This beat rate may be the same or different for each data lane 402, 404, and/or 406. Again, this may be specified by protocol in some instances. It is further noted that while three data lanes are depicted, any number may be utilized.

FIG. 4 depicts that a tracking enable signal may be enabled for longer periods of time if a common signal is used to control multiple data lanes. In other words, for multiple data lanes, some sync packets may generally arrive early (e.g., sync packet 412(1)) and some sync packets may generally arrive late (e.g., sync packet 414(1)). Furthermore, a certain data lane may generally be late and another may generally be early. In order for each phase of the data to be tracked, however, the phase of these sync packets may be tracked in some implementations. Thus, as shown by tracking enable state 408, tracking may be enabled from approximately the time that the earliest sync packet 412(1) arrives until approximately the time that the latest sync packet 414(1) departs. This distance may be termed “lane-to-lane skew” in some instances. If FIG. 4 were an FB-DIMM link, for example, a lane-to-lane skew of 48 unit intervals may exist. Therefore, in this example with a six unit interval sync packet and a lane-to-lane skew of 48 unit intervals, tracking may be enabled for a maximum time period of approximately 54 unit intervals at a time. By doing so, each data phase of data lane 402, 404, and 406 may be tracked and the corresponding data clocks and edge clocks may be adjusted so as to allow for an appropriate sampling position. Of course, while power savings may be lessened, so may the amount and complexity of the corresponding controller circuitry 116.

With this in mind, reference is again made to FIG. 1. Here, an example of system 100 will be illustrated with four receiver phase clocks 120 entering phase interpolator 114 from receiver PLL 118. Remember that data 104, which may be differential data, travels from transmitter 102 and into receiver 106. Receiver 106 may sample data 104 using a half-speed clock, which may occur at sampling amplifier 110 in some implementations. If, for instance, data 104 enters receiver 106 at a rate of 4 Gigabit per second (Gbps), the clock may be running at two Gigahertz (GHz). As shown in FIG. 2, the four clock phases may be equally spaced out. Also as shown in FIG. 2, two of the clock phases may comprise data clocks and may ideally be located at the center of a symbol, while two clocks may comprise edge clocks and may ideally be located at an edge of a symbol. Phase interpolator 114 may serve to create these data clocks and edge clocks. In some instances, phase interpolator 114 may comprise analog circuits that mix the receiver clock phases 120 coming in from receiver PLL 118 in different proportions to give a resultant clock phase that is optimal or approximately optimal for the current data sampling.

Sampling amplifier 110 may then receive the receiver clocks 120 coming from phase interpolator 118 as well as data 104 in the form of an analog signal. Sampling amplifier 110 may then, in some instances, take data 104 and turn it into symbols, such as bytes. In some instances, sampling amplifier 110 may take the analog data signal and turn it into logic 0's and logic 1's, which may result in data 104 taking the form shown in FIG. 2. More specifically, sampling amplifier 110 may take each of the inputted clocks clock a portion of the data into a sample. For instance, sampling amplifier 110 may take a portion of the inputted analog signal and output a sample at phase 0°. It may then take another portion of the analog signal and output a sample at phase 90°, and another at 180°, and another at 270°. In this example, data 104 outputted from sampling receiver 110 may comprise two data samples (samples at the center of the data) and two edge samples (samples at the edge of the data). In this form, Data 104 may travel to other portions of the circuit for processing, and may also travel to sync and align unit 112.

Sync and align unit 112 may function to align these four data samples into one clock phase, namely the clock phase 124 of data recovery circuit 108. As discussed above, data recovery circuit 108 may operate, in some implementations, on a single clock phase 124 which is provided by phase interpolator 114, which in turn is provided by receiver PLL 118. In the instant example, data recovery circuit 108 may run off of either the 90° clock phase or the 270° degree clock phase. Again, these two clock phases fall on data edges rather than data centers. Whichever clock phase data recovery circuit 108 uses, sync and align unit 112 may accordingly align all four data samples into clock phase 124 and provide this input 122 to data recovery circuit 108.

Data recovery circuit 108 may then take input 122 in the form of samples in a single clock phase and determine whether receiver 106 is sampling data 104 at the proper location, such as the approximate center. If data recovery circuit 108 determines that the sampling of receiver 106 is lagging, it may instruct phase interpolator 114 to increment receiver phase clocks 120. If, meanwhile, data recovery circuit 108 determines that the sampling of receiver 106 is leading, it may instruct phase interpolator 114 to decrement receiver phase clocks 120. Of course, data recovery circuit may determine that receiver 106 is sampling at a proper location, and may issue no instructions or may accordingly issue instructions to maintain the current setting. Arrow 126 of FIG. 1 represents these corresponding instructions.

Furthermore, in some instances data recovery circuit 108 may include a filter or the like that helps to determine whether or not receiver phase clocks 120 should be incremented or decremented. In some implementations, the filter may work off of statistics. This means that it may accumulate “votes”, or indications of whether the phase should be incremented or decremented, and net these votes to determine whether or not to issue instructions 126. For instance, the filter may issue instructions if it receives a number of increment requests that is greater than the number of decrement requests by a certain preset threshold value, which may be adjustable.

Furthermore, multiple possibilities exist for the filter when designing a system that selectively tracks phases of incoming data 104. If, for instance, a phase of incoming data 104 is tracked at a beat rate, then the filter may either accumulate votes from one sync packet to the next, or it may discard any votes amassed during one sync packet if that number was not large enough to make an adjustment. In other words, the filter may either rollover votes received during tracking of previous sync packets in deciding whether to alter the phase clocks, or it may only use votes actually received during the current sync packet.

Also as discussed above, portions of receiver 106 and/or data recovery circuit 108 may be turned off for periods of time in which the transmitted clock phase is not expected to drift drastically. When turned back on, the transmitted phase may again be checked and appropriate correction to receiver phase clocks 120 may be made.

In some implementations, the following portions of system 100 may be selectively turned off and on by controller 116 while receiver 106 continues to receive data 104. This means that a phase of a portion of data 104 may not be tracked. In some instances, these portions may comprise components that are related to the sampling of data edges. Components related to data samples (e.g. samples near a center of the data symbol), meanwhile, may remain on in order to allow for data extraction and data processing throughout the rest of the device. In other words, in some instances, the portion of system 100 that pertains to tracking the phase may be turned off, while the portion that pertains to actually extracting incoming data 104 and providing it to other portions of the device may remain on.

First, half of the circuit comprising phase interpolator 114 may be turned off. In some instances, this portion may comprise the portion of receiver phase clocks 120 that pertain to edges. In the example having four phase clocks, the portion of phase interpolator related to the edge clocks at 90° and 270° may be shut down. Furthermore, in some instances half of the circuit comprising sampling receiver 110 may be shut down. Again, this portion may comprise the portion relating to the output of edge samples.

Sync and align unit 112 as well as data recovery circuit 108 may also be shut down in some implementations. As such, data recovery circuit 108 may not issue instructions 126 telling phase interpolator 114 to increment or decrement the phase clocks. This may cause phase interpolator 114 to continue generating its data clocks in a last known position, until data recovery circuit 108 reawakens and provides instructions to the contrary. This may allow for data 104 to be processed while the transmitted phase is not expected to substantially drift. In some instances described above, a power savings of approximately 50% or more may be achieved as compared to a system having a feedback loop that constantly monitors the phase of data 104.

As depicted in FIG. 1, controller 116 may selectively enable and disable tracking of a phase of incoming data 104. As such, controller 116 may turn on and off the feedback loop circuitry as discussed immediately above. Controller 116 may send a tracking enable and/or disable signal to many of the components individually, or to one or more components that may propagate the signal themselves. For instance, controller 116 may send a tracking signal to data recovery circuit 108, phase interpolator 114, sync and align unit 112, and/or sampling receiver 110. In some instances, the enable or disable signal may be synchronous, while in others it may be an asynchronous signal. Furthermore, it is noted that a state machine residing in the core of the host device may provide controller 116 and the corresponding tracking signal. In some instances, this state machine may reside in the logical link layer of the device. As discussed above in regards to FIGS. 2-4, tracking may be selectively enabled at a beat rate, at another rate, or even randomly. As such, system 100 may reduce power without having a noticeable effect on its performance.

Exemplary Methods

FIG. 5 is a flow diagram that illustrates one non-limiting exemplary method 500 in accordance with an embodiment described herein. Act 502 may comprise receiving data comprising bits over a serial communication link. As discussed above, any suitable serial link can be utilized to receive the data. Act 504 may comprise cycling between tracking a phase of the received data to detect an approximate center of a bit and shutting down circuitry associated with the tracking of the phase, such that at least a portion of the received data is not tracked. Any suitable techniques can be utilized for detecting and for shutting down the circuitry, non-limiting examples of which are given above.

Exemplary System

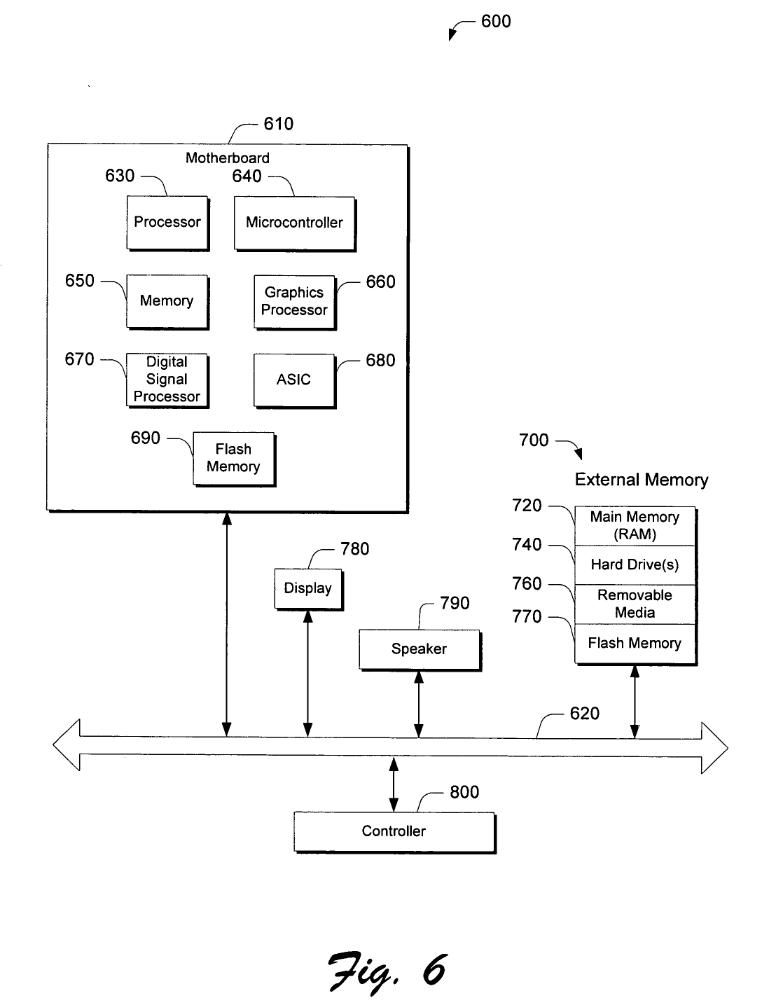

FIG. 6 depicts a block diagram of an exemplary electronic system 600 that may include serial communication links, such as those described above. Such electronic system 600 may comprise a computer system that includes a motherboard 610 which is electrically coupled to various components in electronic system 600 via a system bus 620. System bus 620 may be a single bus or any combination of busses.

Motherboard 610 can include, among other components, one or more processors 630, a microcontroller 640, memory 650, a graphics processor 660 or a digital signal processor 670, and/or a custom circuit or an application-specific integrated circuit 680, such as a communications circuit for use in wireless devices such as cellular telephones, pagers, portable computers, two-way radios, and similar electronic systems and a flash memory device 690.

Electronic system 600 may also include an external memory 700 that in turn may include one or more memory elements suitable to the particular application. This may include a main memory 720 in the form of random access memory (RAM), one or more hard drives 740, and/or one or more drives that handle removable media 760, such as floppy diskettes, compact disks (CDs) and digital video disks (DVDs). In addition, such external memory may also include a flash memory device 770.

Electronic system 600 may also include a display device 780, a speaker 790, and a controller 800, such as a keyboard, mouse, trackball, game controller, microphone, voice-recognition device, or any other device that inputs information into electronic system 600.

### CONCLUSION

Although the embodiments have been described in language specific to structural features and/or methodological acts, it is to be understood that the subject matter defined in the appended claims is not necessarily limited to the specific features or acts described. Rather, the specific features and acts are disclosed as exemplary forms of implementing the claimed subject matter.

What is claimed is:

1. An apparatus comprising:
a receiver to receive data over a serial communication link; and
a data recovery circuit coupled to the receiver and configured to selectively track, responsive to a tracking signal, at least one phase of the data to align at least one phase clock.

2. An apparatus as described in claim 1, further comprising a controller configured to enable or disable the tracking signal.

3. An apparatus as described in claim 1, wherein the data comprises one or more bits, each bit comprising a center and an edge, and wherein the receiver is further configured to sample the data approximately at the center of the one or more bits based, at least in part, on the aligned phase clock.

4. An apparatus as described in claim 1, wherein the data includes multiple training packets each comprising a threshold number of symbol transitions and each packet being approximately separated by a predetermined amount of time, and wherein the data recovery circuit is to selectively track the phase of the data at one or more of the multiple training packets.

5. An apparatus as described in claim 4, wherein the data recovery circuit generally does not track the phase of the data at portions of the data not comprising the training packets.

6. An apparatus as described in claim 1, wherein the data recovery circuit operates on a single clock phase and wherein the receiver comprises:
a phase interpolator to output one or more data clocks having a phase that allows for sampling of the data and one or more edge clocks having another phase that allows for sampling of edges of the data;
one or more sampling receivers to receive the data from a transmitter and the one or more data clocks and the one or more edge clocks from the phase interpolator in order to output data samples and edge samples; and
a sync and align unit configured to receive the data and edge samples from the sampling receivers and align these samples in the single clock phase of the data recovery circuit.

7. An apparatus as described in claim 6, wherein when the tracking signal is not enabled, at least some of the following elements are shut down: the data recovery circuit, the edge clocks, a sampling receiver, or the sync and align unit.

8. An apparatus comprising:
a serial communication link receiver to receive and sample incoming data having a phase of a transmitter clock; and
a feedback loop coupled to the receiver and configured to intermittently track the phase of the incoming data and adjust a sampling position based on the tracked phase such that at least a portion of the data is not tracked.

9. An apparatus as described in claim 8, wherein at least a portion of the feedback loop is turned off when the feedback loop is not tracking the phase of the incoming data.

10. An apparatus as described in claim 8, wherein the feedback loop is to adjust the sampling position by incrementing or decrementing a sampling position of one or more data clocks and one or more edge clocks so that the data clock sampling position approximates a center of a symbol of the data and the edge clock sampling position approximates an edge of the symbol of the data.

11. An apparatus as described in claim 8, wherein the incoming data comprises data traveling over multiple data lanes, and further comprising a controller configured to transmit a common tracking signal to enable or disable tracking of phases for data traveling over each of the multiple data lanes.

12. An apparatus as described in claim 8, wherein the incoming data comprises data traveling over multiple data lanes, and further comprising a serial communication link receiver and controller for each data lane, each controller configured to transmit a tracking signal to enable or disable tracking of a phase of the data traveling over the corresponding data lane.

13. An apparatus as described in claim 8, wherein the feedback loop is to track the phase of the incoming data and adjust the sampling position during arrival of sync packets.

14. An apparatus as described in claim 14, wherein the feedback loop generally does not track the phase during portions of the incoming data not comprising sync packets.

15. An apparatus as described in claim 8, wherein the feedback loop intermittently tracks the phase according to a beat rate, the beat rate being an amount of time between sync packets.

16. An apparatus as described in claim 15, wherein the feedback loop tracks the phase once every whole number multiple of a beat rate.

17. A method comprising:
receiving data comprising bits over a serial communication link; and
cycling between tracking a phase of the received data to detect an approximate center of a bit and shutting down circuitry associated with the tracking of the phase such that at least a portion of the received data is not tracked.

18. A method as described in claim 17, further comprising adjusting a sampling position of the received data in response to the tracking of the phase.

19. A method as described in claim 17, wherein the receiving of the data comprises receiving sync packets including a threshold number of bit transitions in a threshold period of time.

20. A method as described in claim 19, further comprising measuring a time between two sync packets in order to determine a beat rate.

21. A method as described in claim 20, wherein the time between tracking cycles approximately comprises a whole number multiple of the beat rate.

22. An electronic system comprising:
a processor to perform one or more operations, the processor comprising:
a receiver to receive incoming data signals from a transmitter over a serial communication link and sample data from the incoming data signals; and
a data recovery circuit to selectively track a clock phase of the transmitter to enable the receiver to sample the data at an approximate center portion of the data; and
a controller to provide input commands to perform at least one of the one or more operations.

23. An electronic system as described in claim 22, wherein the data recovery circuit and at least a portion of the receiver are turned off when the data recovery circuit is not tracking the transmitter clock phase.

24. An electronic system as described in claim 22, wherein the data recovery circuit or a portion of the receiver is further configured to delay or advance a data sampling position of the receiver in response to the tracking of the transmitter clock phase.
